(19) United States
(12) Patent Application Publication
(10) Pub. No.: US 2005/0189536 A1
(43) Pub. Date: Sep. 1, 2005

(54) Self-assembly organic dielectric layers based on phosphonic acid derivatives

(76) Inventors: Ute Zschieschang, Erlangen (DE); Hagen Klauk, Erlangen (DE); Marcus Halik, Erlangen (DE); Guenter Schmid, Hemhofen (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/066,617

(22) Filed: Feb. 28, 2005

(30) Foreign Application Priority Data
Feb. 27, 2004 (DE) 10 2004 009 600.7

(51) Int. Cl. H01L 29/08

(52) U.S. Cl. 257/40

(57) ABSTRACT

A field effect transistor includes a gate dielectric with a self-assembled monolayer of an organic compound, where the organic compound includes a phosphonic acid group. The phosphonic acid group additionally has an organic radical selected from the group consisting of (a) an alkyl chain including 1 to 20 carbon atoms, (b) oligo(thio)ether chains and/or c) aromatic or heteroaromatic compounds. In addition, a method for fabricating a field effect transistor includes forming a self-assembled monolayer of an organic compound as a gate dielectric, where the organic compound includes a phosphonic acid group.

### CROSS REFERENCE TO RELATED APPLICATIONS

This application claims priority under 35 USC §119 to German Application No. DE 10 2004 009 600.7, filed on Feb. 27, 2004, and titled “Self-Assembly Organic Dielectric Layers Based on Phosphonic Acid Derivatives,” the entire contents of which are hereby incorporated by reference.

### FIELD OF THE INVENTION

The invention relates to transistors, in particular field effect transistors, including organic dielectric layers.

### BACKGROUND

High-quality, extremely thin dielectric layers are of considerable interest for a multiplicity of applications. In particular, the realization of inexpensive electronics on large-area flexible substrates that operate with low supply voltages requires the availability of such layers for constructing transistors, capacitors, etc. By way of example, organic field effect transistors are suitable as pixel control elements in active matrix screens. Such screens are usually produced with field effect transistors based on amorphous or polycrystalline silicon layers. The use of rigid and fragile glass or quartz substrates is typically required due to the high temperatures (typically more than 250° C.) that are necessary for fabricating high-quality transistors including such amorphous or polycrystalline silicon layers. In contrast, transistors based on organic semiconductors are fabricated at relatively low temperatures at which (typically less than 200° C.) and thus permit the production of active matrix screens using inexpensive, flexible, transparent, and unbreakable polymer films that have considerable advantages over glass or quartz substrates.

A further area of application for organic field effect transistors is the fabrication of inexpensive integrated circuits for use, for example, as transponders for active labeling and identification of merchandise and goods. These transponders are usually produced using integrated circuits based on monocrystalline silicon, which leads to considerable costs in the construction and connection technology. Producing transponders on the basis of organic transistors would lead to enormous cost reductions and could assist transponder technology en route to a worldwide breakthrough.

The fabrication of thin-film transistors usually requires a large number of steps in which the different layers of the transistor are deposited. In a first step, the gate electrode is deposited on a substrate, then the gate dielectric is deposited on the gate electrode, and the source and drain electrodes are patterned in a further step. In the last step, the semiconductor is deposited between the source and drain electrodes on the gate dielectric. Significant endeavors are being made on the one hand to simplify the fabrication process and on the other hand to fabricate thin-film field effect transistors with smaller dielectric layer thicknesses, since the latter directly determine the supply voltage required.

German patent applications DE 103 28 810 and DE 103 28 811 describe the preparation and use of molecules, referred to as T-SAMs (“top-linked self-assembly monolayers”), which serve as an insulator layer and may be used for organic field effect transistors. These two applications are incorporated herein by reference in their entireties. The molecular structures described therein are particularly suitable for forming monolayers on silicon substrates with a natural silicon oxide layer. When other gate materials are utilized, for example aluminum and titanium, which are advantageous for constructing integrated circuits on glass or flexible polymer substrates and which, due to the formation of a natural oxide layer, are likewise suitable substrates for the formation of monolayers made from molecules of the compounds described in DE 103 28 810 and DE 103 28 811, organic field effect transistors having the T-SAM insulator layers in conjunction with pentacene, tetracene and oligothiophenes exhibit poor electrical properties in comparison with utilizing silicon as gate material.

### SUMMARY OF THE INVENTION

An object of the present invention is to provide new classes of compounds that can serve as a monomolecular dielectrics for use in field effect transistors based on organic semiconductors.

Another object of the present invention is to provide field effect transistors having a dielectric layer which can serve both for field effect transistors based on silicon and for field effect transistors based on organic semiconductor materials.

A further object of the invention is to provide a variety of materials that can be used in the fabrication of field effect transistors.

The aforesaid objects are achieved individually and/or in combination, and it is not intended that the present invention be construed as requiring two or more of the objects to be combined unless expressly required by the claims attached hereto.

In accordance with the present invention, a field effect transistor (FET) comprises a substrate, a source electrode, a drain electrode, a gate electrode, and a semiconductor material. The field effect transistor further comprises a dielectric layer (gate dielectric) formed from a self-assembled monolayer of an organic compound that includes a phosphoric acid group, where the dielectric layer is arranged on the gate electrode.

In an exemplary embodiment, the organic compound of the FET has the following formula I: 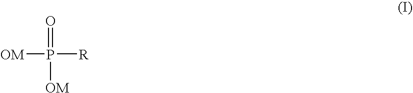
wherein:
M comprises at least one of hydrogen, an organic compound and a metal cation; and
R is at least one of:
(a) an alkyl chain comprising 1 to 20 carbon atoms that are linear or branched and/or substituted and/or contain an unsaturated bond, with an n-alkyl chain of the formula —(CH₂)ₓ—CH₃ being particularly preferred, where x is an integer from 0 to 19;
(b) an oligothioether chain having the following formula II:
   [—(CH₂—CH₂—X)ₙ—] (II)
where X is O or S and n is an integer from 2 to 10;
(c) a chain having the following formula III: 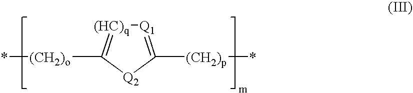
where m is an integer from 1 to 5, o is an integer from 0 to 3, p is an integer from 0 to 3, q is 1 or 2, and Q₁ and Q₂ are independent of each other and each comprises at least one of C—H, O, S and N—H; and
(d) any of the radicals phenyl, biphenyl, terphenyl, quaterphenyl, (oligo)thiophene, (oligo)pyrrole, (oligo)imidazole, (oligo)pyridine, (oligo)pyrazine.

In addition, the substituent R can further comprise a combination of the chains described above in (a) and (b), a combination of the chains described above in (a) and (c), or a combination of the chains described above in (a), (b) and (c).

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIG. 1 depicts a schematic representation of a gate electrode for a field effect transistor and including a self-assembled monolayer of the organic compound in accordance with the present invention.

FIG. 2 depicts an exemplary embodiment of a bottom contact FET in accordance with the present invention.

FIG. 3 depicts an exemplary embodiment of a top contact FET in accordance with the present invention.

FIG. 4 depicts an exemplary embodiment of a bottom contact FET providing a higher supply voltage in accordance with the present invention.

FIG. 5 depicts an exemplary embodiment of a top contact FET providing a higher supply voltage in accordance with the present invention.

FIG. 6 is a diagram showing voltage characteristic curves of a field effect transistor formed in accordance with the present invention.

FIG. 7 is a diagram showing on-state characteristic curves of a field effect transistor formed in accordance with the present invention.

### DETAILED DESCRIPTION

In accordance with the present invention, a field effect transistor (FET) is constructed including a substrate with a source electrode, a drain electrode, a gate electrode, and a semiconductor material. The FET further includes a dielectric layer (gate dielectric) formed from a self-assembled monolayer of an organic compound arranged on the gate electrode, where the organic compound includes a phosphoric acid group.

The dielectric layers formed according to the invention are so stable that it is possible to carry out photolithography processes on their surfaces such as, for example, deposition and patterning of further metal layers, deposition of an organic or inorganic semiconductor, etc. Electronic components, such as organic field effect transistors, for example, can thus be fabricated and be extended to form integrated circuits.

In an exemplary embodiment, the organic compound of the FET has the following formula I: 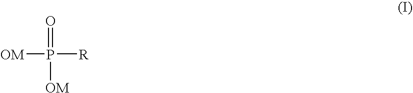
where:
M comprises at least one of hydrogen, an organic compound and a metal cation; and
R is at least one of:
(a) an alkyl chain comprising 1 to 20 carbon atoms that are linear or branched and/or substituted and/or contain an unsaturated bond, with an n-alkyl chain of the formula —(CH₂)ₓ—CH₃ being particularly preferred, where x is an integer from 0 to 19;
(b) an oligothioether chain having the following formula II:
   [—(CH₂—CH₂—X)ₙ—] (II)
where X is O or S and n is an integer from 2 to 10; and
(c) a chain having the following formula III: 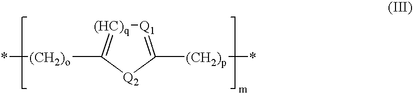
where m is an integer from 1 to 5, o is an integer from 0 to 3, p is an integer from 0 to 3, q is 1 or 2, and Q₁ and Q₂ are independent of each other and each comprises at least one of C—H, O, S and N—H; and
(d) any of the radicals phenyl, biphenyl, terphenyl, quaterphenyl, (oligo)thiophene, (oligo)pyrrole, (oligo)imidazole, (oligo)pyridine, (oligo)pyrazine.

In addition, the substituent R can further comprise a combination of the chains described above in (a) and (b), a combination of the chains described above in (a) and (c), or a combination of the chains described above in (a), (b) and (c).

In general, all organic radicals are suitable which form mobile or rigid linear units with the groups presented under (a), (b) and (c) as set forth above. The length of the radical determines not only the flexibility and the orientation of the self-assembled monolayer but also the thickness of the insulation layer and thus the magnitude of the supply voltage in the component. A suitable combination of linear, flexible and aromatic or heteroaromatic molecular fragments in the organic radical may even contribute to an improvement of the layer properties, to be precise in such a way that the incorporation of aromatic or heteroaromatic groups results in a stabilization of the layer that is based on the ππ interaction of identical groups of adjacent chains. Besides the groups mentioned above, there may also be further groups in the organic radical in order, on the one hand, to determine the orientation of the molecule and, on the other hand, to give a stabilization through interactions such as, for example, dipole-dipole, CT interactions, ππ interactions or through a stabilization by means of van der Waals forces. In this case, the materials according to the invention are oriented on the surface of the gate electrode in such a way that the phosphonic acid group, serving as an anchor group, occupies the oxidic substrate surface in the densest possible manner and the linear organic radicals are arranged parallel to adjacent radicals away from the substrate surface. The parallel orientation of the organic radicals is generally not achieved orthogonally with respect to the substrate, but rather by forming an angle, where the magnitude of the angle is not critical.

The thickness of the self-assembled monolayer (layer thickness) is determined by the length of the organic molecule. In a preferred embodiment, the dielectric layer has a thickness of about 1 nm to about 10 nm, preferably of about 2 nm to about 5 nm.

Suitable materials for the gate electrode are, in principle, all materials which either have a native oxide layer or which interact with the phosphonic acid groups. In a particular embodiment, the surface of the gate electrode has a metal oxide layer. It should be noted, however, that other metal layers can also interact with the phosphonic acid groups, which leads to the formation of a self-assembled monolayer. In an exemplary embodiment, such surfaces are hydroxy oxide surfaces.

The preferred materials for the gate electrode are aluminum (Al), titanium (Ti), titanium nitride (TiN), tantalum (Ta), tantalum nitride (TaN), tungsten (W), titanium tungsten (TiW), tantalum tungsten (TaW), tungsten nitride (WN), tungsten carbonitride (WCN), iridium oxide (IrO), ruthenium oxide (RuO), strontium ruthenium oxide (SrRuO) or a combination of these layers and/or materials. In certain situations, when appropriate, the gate electrode also includes a layer made of silicon (Si), titanium nitride silicon (TiNSi), silicon oxynitride (SiON), silicon oxide (SiO), silicon carbide (SiC) or silicon carbonitride (SiCN). If the electrode material does not have a native oxide layer, the surface can be treated in a targeted manner in order to obtain either an oxide layer or a different layer, which interact with the phosphonic acid groups.

It is necessary for the surface of the gate electrode to be configured such that an interaction with phosphonic acid groups is possible.

The materials for the source and drain electrodes are not critical for the function of the component insofar as there is no direct interaction (binding, etc.) of the phosphonic acid compounds according to the invention. All conductive metals, formulations thereof, or polymers are suitable as materials for the source and drain electrodes. The following materials are mentioned by way of example: gold (Au), silver (Ag), copper (Cu), titanium (Ti), titanium nitride (TiN), tantalum (Ta), tantalum nitride (TaN), tungsten (W), titanium tungsten (TiW), tantalum tungsten (TaW), tungsten nitride (WN), tungsten carbonitride (WCN), iridium oxide, ruthenium oxide, strontium ruthenium oxide, platinum, palladium, gallium arsenide, etc. The source and/or drain electrode may also additionally have a layer made of Si, TiNSi, SiON, SiO, SiC or SiCN. Examples of suitable polymeric contact materials are PEDOT:PSS (Baytron®) or polyaniline.

The dielectric layer according to the invention including an organic compound with phosphonic acid groups is suitable particularly when a semiconductor material formed on the basis of an organic semiconductor is used. The term “phosphoric acid group” or “phosphonic acid group”, as used herein, refers to any chemical groups containing phosphoric acid or phosphoric acid derivatives including, without limitation, FsW or salts.

The semiconductor material is constructed based upon an organic semiconductor. The organic semiconductor can be selected, for example, from the group consisting of pentacene, tetracene and oligothiophene.

The supply voltage of a field effect transistor depends in particular on the thickness of the dielectric layer (gate dielectric) arranged on the gate electrode. Therefore, the field effect transistor according to the invention can be operated with a supply voltage of less than 5 volts and in particular of less than 3 volts, namely in the range of 1 to 3 volts. If a higher supply voltage is desired, however, an inorganic or organic insulation layer, for example, can be applied to the surface of the self-assembled monolayer. If the insulation layer is formed on the basis of an organic polymer, by way of example, the layer has a thickness of 10 to 30 nm.

The field effect transistors according to the invention are suitable in particular for use in the so-called “low cost” area of electronics, and especially for organic field effect transistors with low supply voltages.

In one embodiment of the invention, a fabrication method for fabricating field effect transistors includes providing a substrate based on inorganic or organic materials, and depositing a gate electrode on the substrate. The gate electrode is then brought into contact with an organic compound, which has a phosphonic acid group, in order to obtain a self-assembled monolayer of the organic compound arranged on the gate electrode. As described above, the surface of the gate electrode has properties such that the phosphonic acid group interacts with the surface of the gate electrode. The self-assembled monolayer of the organic compound obtained in this way can then be subjected to further fabrication steps. The next step in the method is the deposition and patterning of a source electrode and a drain electrode with the subsequent deposition of a semiconductor material.

The organic compound can be brought into contact with the material of the gate electrode, for example, by dipping a substrate with the gate electrode arranged thereon into a solution having the organic compound. Suitable solvents are in particular protic, polar solvents, such as alcohol, for example. The density of the self-assembled monolayer of the organic compound and the deposition duration can be influenced by the concentration of the solution of the organic compound into which the substrate is dipped. For fabricating a dense layer, the concentration of the organic compound in the solution is preferably in the range of about 10⁻⁴ mol % to 0.1 mol %. After the substrate has been dipped into the solution of the organic compound, a rinsing step with pure processed solvent is subsequently carried out. Afterward, if appropriate, the substrate is rinsed with a readily volatile solvent such as, for example, acetone or dichloromethane, and is then dried. The drying can be carried out, for example, in a furnace or on a hot plate under protective gas.

Alternatively, the organic compound can be brought into contact with the gate electrode by vapor deposition of the organic compound onto the gate electrode. In an exemplary embodiment, the organic compound is deposited in a closed reactor with heating. The interior of the reactor is evacuated after loading with the substrate with a defined gate electrode and is ventilated with inert gas such as, for example, argon or nitrogen, in order to remove oxygen residues. Working pressures and working temperatures are then established depending upon the organic radical utilized. A pressure of about 10⁻⁶ mbar to about 400 mbar and a temperature of about 80° C. to about 200° C. are preferred. The ideal process conditions depend on the volatility of the organic compound. The coating times are generally between 3 min and 24 hours, depending on process conditions.

One of the objects is achieved by the use of an organic compound, which has a phosphonic acid group, in the fabrication of field effect transistors.

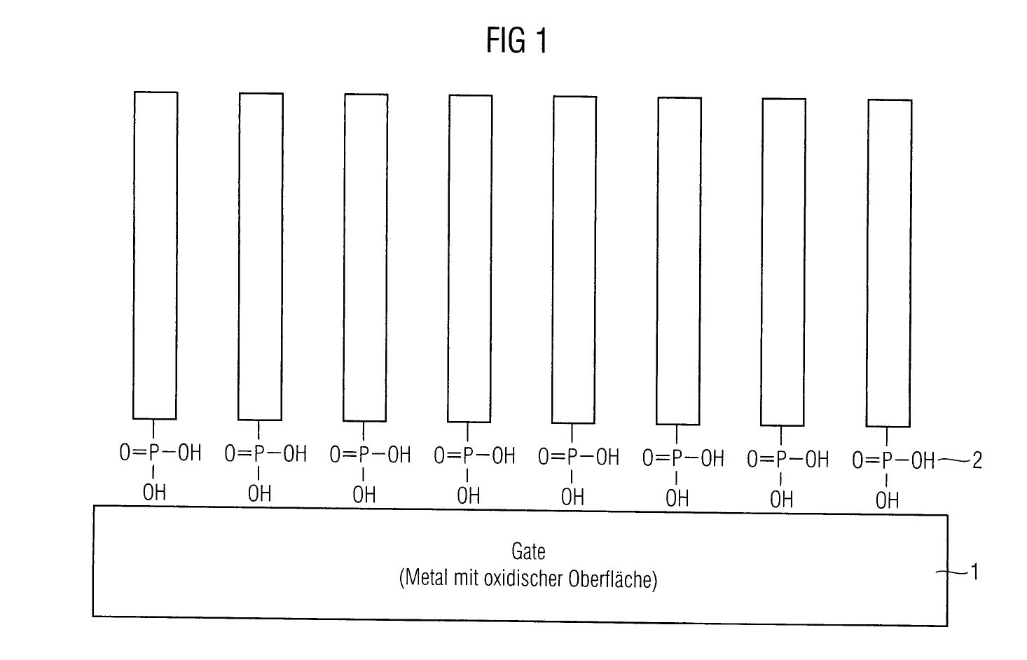

In a particular embodiment, the organic compound with the phosphonic acid group forms a self-assembled monolayer on the gate electrode, where the organic compound serves as a gate dielectric, as depicted in FIG. 1. In particular, a gate electrode 1 includes a metal oxide layer, so that an interaction between phosphonic acid groups and the surface of the gate electrode can take place. The metal oxide results in a strong interaction between the surface and the phosphonic acid groups 2 that form the self-assembled monolayer on the gate electrode.

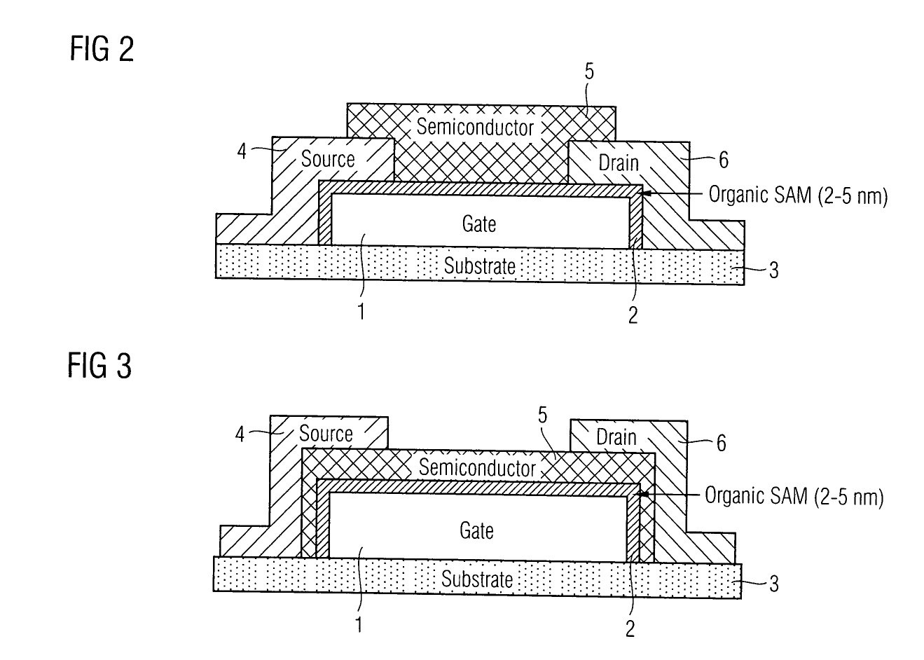

FIG. 2 depicts an embodiment of a field effect transistor with a self-assembled monolayer of an organic compound according to the invention. In particular, a gate electrode 1 is arranged on a substrate 3. After patterning, the gate electrode is brought into contact with the organic compound (e.g., in any manner as described above) in order to obtain a self-assembled monolayer of the organic compound 2. Source and drain electrodes 4 and 6 are then deposited and patterned and a layer 5 of an organic semiconductor is deposited on surface portions of the source, drain and gate electrodes. The construction of the field effect transistor (FET) depicted in FIG. 2 has a bottom contact architecture. In an alternative embodiment depicted in FIG. 3, an FET is constructed with a self-assembled monolayer 2 in accordance with the invention and having a top contact architecture.

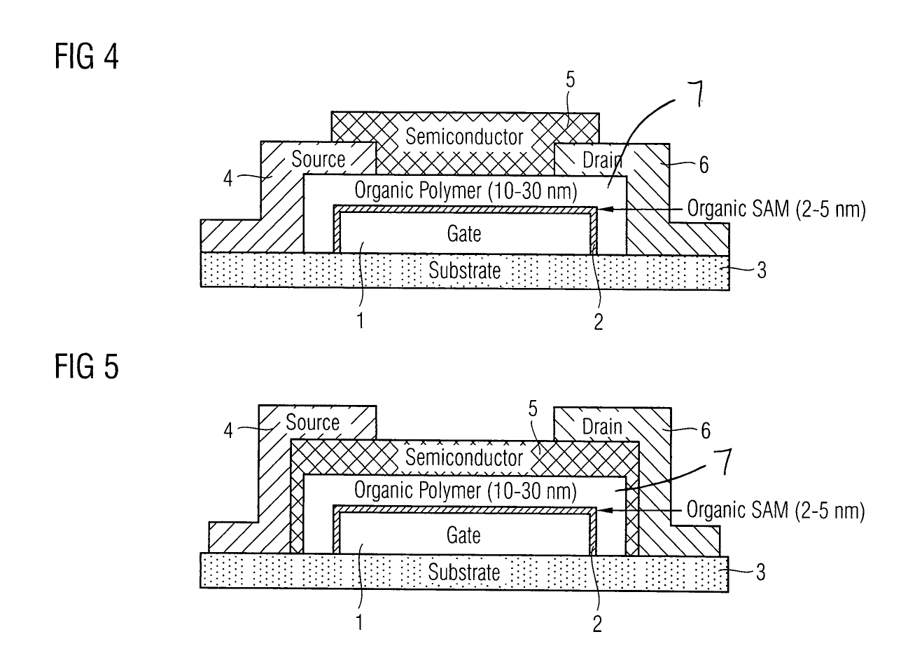

The embodiments depicted in FIGS. 4 and 5 respectively correspond with the embodiments of FIGS. 2 and 3, with the difference being that a further dielectric layer 7 is arranged on the self-assembled monolayer 2 of the organic compound, resulting in a higher supply voltage for the FETs of FIGS. 4 and 5. The further dielectric layer 7 has a thickness of about 10 to about 30 nm and is composed of an organic polymer.

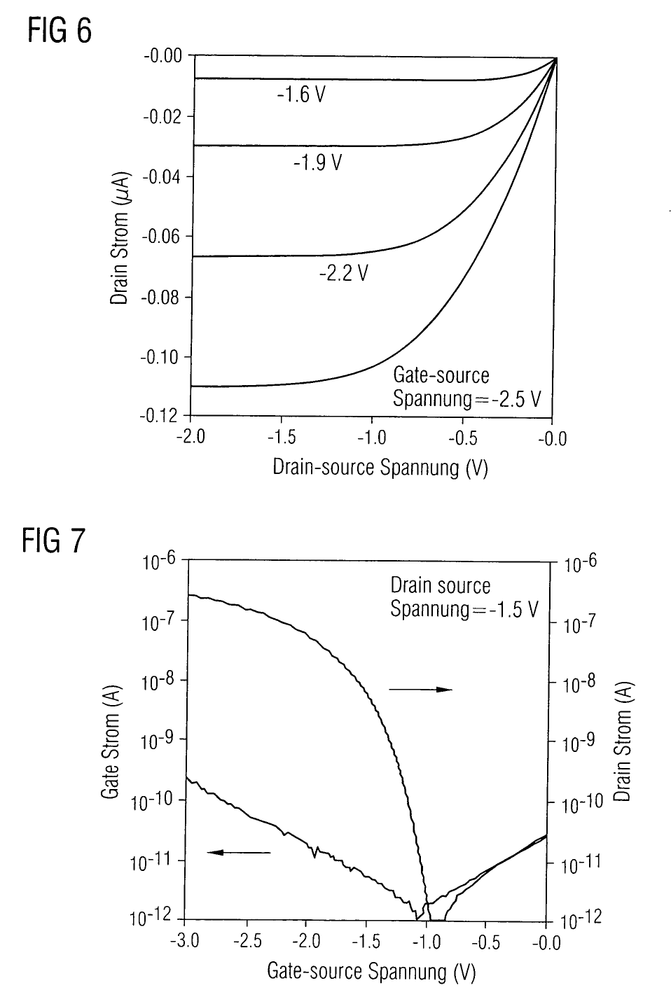

The electronic properties of an organic field effect transistor formed in accordance with the present invention is shown in FIGS. 6 and 7. The organic field effect transistor was obtained by depositing alkane phosphonic acid on an aluminum gate electrode. The self-assembled monolayer of the alkane phosphonic acid has a thickness of about 2.5 nm. The source and drain contacts are made of gold and the semiconductor material was pentacene.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### REFERENCE SYMBOLS

1 gate electrode
2 monolayer of the organic compound
3 substrate
4 source electrode
5 semiconductor
6 drain electrode
7 further dielectric layer

1. A field effect transistor comprising a substrate, a source electrode, a drain electrode, a gate electrode, a semiconductor material, and a dielectric layer arranged on the gate electrode and formed from a self-assembled monolayer comprising an organic compound, wherein the organic compound comprises a phosphonic acid group.

2. The field effect transistor of claim 1, wherein the organic compound has the following formula I: 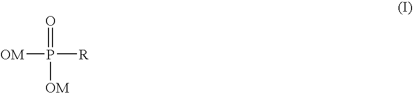
wherein:
M comprises at least one of hydrogen, an organic compound and a metal cation; and
R is at least one of:
(a) an alkyl chain comprising 1 to 20 carbon atoms;
(b) an oligothioether chain having the following formula II:
[—(CH₂—CH₂—X)ₙ—] (II)
where X is O or S and n is an integer from 2 to 10;
(c) a chain having the following formula III: 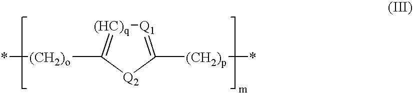
where m is an integer from 1 to 5, o is an integer from 0 to 3, p is an integer from 0 to 3, q is 1 or 2, and Q₁ and Q₂ are independent of each other and each comprises at least one of C—H, O, S and N—H; and
(d) any of the radicals phenyl, biphenyl, terphenyl, quaterphenyl, (oligo)thiophene, (oligo)pyrrole, (oligo)imidazole, (oligo)pyridine, (oligo)pyrazine.

3. The field effect transistor of claim 2, wherein R comprises a combination of the chains described above in (a) and (b), a combination of the chains described above in (a) and (c), or a combination of the chains described above in (a), (b) and (c).

4. The field effect transistor of claim 2, wherein R has the formula —(CH₂)ₙ—CH₃, where x is an integer from 0 to 19.

5. The field effect transistor of claim 1, wherein the dielectric layer includes a thickness of 2 nm to about 10 nm.

6. The field effect transistor of claim 1, wherein the gate electrode includes a metal oxide layer at a surface of the gate electrode that contacts the dielectric layer.

7. The field effect transistor of claim 1, wherein the gate electrode is formed from a material selected from the group consisting of aluminum (Al), titanium (Ti), titanium nitride (TiN), tantalum (Ta), tantalum nitride (TaN), tungsten (W), titanium tungsten (TiW), tantalum tungsten (TaW), tungsten nitride (WN), tungsten carbonitride (WCN), iridium oxide, ruthenium oxide, strontium ruthenium oxide, silicon, titanium nitride silicon, silicon oxynitride, silicon oxide, silicon carbide, silicon carbonitride, and combinations thereof.

8. The field effect transistor of claim 1, wherein each of the source and drain electrodes, independently of each other, is formed from a material selected from the group consisting of gold (Au), silver (Ag), copper (Cu), titanium (Ti), titanium nitride (TiN), tantalum (Ta), tantalum nitride (TaN), tungsten (W), titanium tungsten (TiW), tantalum tungsten (TaW), tungsten nitride (WN), tungsten carbonitride (WCN), iridium oxide (IrO), ruthenium oxide (RuO), strontium ruthenium oxide (SrRuO), platinum (Pt), palladium (Pd), gallium arsenide, silicon (Si), titanium nitride silicon (TiNSi), silicon oxynitride (SiON), silicon oxide (SiO), silicon carbide (SiC), silicon carbonitride (SiCN), and combinations thereof.

9. The field effect transistor of claim 1, wherein the semiconductor material comprises an organic semiconductor material.

10. The field effect transistor of claim 9, wherein the organic semiconductor material is selected from the group consisting of pentacene, tetracene and oligothiophene.

11. The field effect transistor of claim 1, wherein the semiconductor material is an inorganic semiconductor material.

12. The field effect transistor of claim 1, wherein the field effect transistor is operable with a supply voltage of less than 5 volts.

13. A method for fabricating a field effect transistor comprising:
providing a substrate;
depositing a gate electrode on the substrate;
contacting the gate electrode with an organic compound, the organic compound including a phosphonic acid group, so as to obtain a self-assembled monolayer of the organic compound on the gate electrode;
deposition of a source electrode and a drain electrode on the substrate; and
deposition of a semiconductor material on the substrate.

14. The method of claim 13, wherein the organic compound is provided in a solvent during contacting with the gate electrode.

15. The method of claim 14, wherein the solvent is a protic, polar solvent.

16. The method of claim 14, wherein the solvent is an alcohol.

17. The method of claim 14, wherein the concentration of the organic compound within the solvent is in the range of about 104 mol % to about 0.1 mol %.

18. The method of claim 13, wherein the organic compound is brought into contact with the gate electrode via vapor deposition of the organic compound onto the gate electrode.

19. The method of claim 18, wherein the pressure during the vapor deposition of the organic compound on the gate electrode is in the range of about 10⁻⁶ bar to about 400 mbar.

20. The method of claim 18, wherein the temperature during the vapor deposition of the organic compound onto the gate electrode is in the range of about 80° C. to about 200° C.
